(19) United States
(12) Patent Application Publication
(10) Pub. No.: US 2023/0044390 A1
(43) Pub. Date: Feb. 9, 2023

(54) DISPLAY DEVICE

(71) Applicant: AUO Corporation, Hsin-Chu (TW)

(72) Inventors: YU-HAN CHIANG, Hsin-Chu (TW); SHANG-CHIANG LIN, Hsin-Chu (TW); KUN-CHENG TIEN, Hsin-Chu (TW)

(21) Appl. No.: 17/861,609

(22) Filed: Jul. 11, 2022

(30) Foreign Application Priority Data
Aug. 4, 2021 (TW) 110128775

(51) Int. Cl. H01L 27/15; H01L 33/60

(52) U.S. Cl. CPC H01L 27/156; H01L 33/60

(57) ABSTRACT

A display device including a substrate and a light source array disposed on the substrate is provide. The light source array includes a plurality of light-emitting units disposed on the substrate, and each light-emitting unit has a light source and an optical component. Each light source is disposed on the substrate and has a light emitting surface. Each optical component has a light receiving surface and a light exit surface, and each optical component is disposed on the light source with the light receiving surface connected to the light emitting surface. The optical component also has a side surface connecting the light receiving surface and the light exit surface. The side surface and the light receiving surface have an included angle between 100 and 130 degrees within the optical component.

### CROSS-REFERENCE TO RELATED APPLICATION

This application claims the priority benefit of Taiwan Application No. 110128775, filed on Aug. 4, 2021. The entirety of each of the above-mentioned patent applications is hereby incorporated by reference herein and made a part of this specification.

### BACKGROUND OF THE INVENTION

### 1. Field of the Invention

The present invention relates to a display device; specifically, the present invention relates to a display device having a light source with increased luminance efficiency.

### 2. Description of the Prior Art

Along with the advancement of display panel technologies, the aim of the display panel industry has turned towards higher image quality. In addition, currently there is a trend in the industry to go from backlight-emitting towards active light-emitting. Active light-emitting panels have advantages such as thinness, flexibility, wide color gamut, wide viewing angle, high contrast, high HDR, etc., allowing them to show good image quality of the display panel and can be applied to various products.

An active light-emitting display device can be made using a plurality of light-emitting light sources such as Mini LED or Micro LED. Taking the Mini LED for example, its luminance efficiency can be classified into internal luminance efficiency and external luminance efficiency. The internal luminance efficiency will be determined according to growth materials and crystalline integrity of the light-emitting diode. The current technology of epitaxy has been comparatively developed; however, light is reflected by the surface and absorbed by the material itself in the structure, so that only 10% or less than 10% of the light emitted by the light-emitting diode reaches the receiver outside the device. Therefore, enhancing the external luminance efficiency of the light-emitting diode is a very important subject

In addition, LED display device can be made by overlapping multiple layers of the metals so that the whole reflectivity is higher, resulting in poor visibility. Therefore, the aforementioned problems need to be overcome using a structure with lower reflectivity.

### SUMMARY OF THE INVENTION

Therefore, the present invention intends to provide a display device which can enhance the luminance efficiency of the light source.

The present invention also intends to provide a display device which can decrease light loss issues such as light reflection or refraction.

The display device includes a substrate and a light source array, wherein the light source array includes a plurality of light emitting units arranged on the substrate. Each of the light emitting unit includes a light source and an optical component. The light source is arranged on the substrate and the side of the light source opposite to the substrate has a light source luminous surface. The optical component is disposed on the light source. Each of the optical components has a light receiving surface and a light emitting surface, and the light receiving surface is connected to the light source luminous surface. The optical component has a side surface connecting the light receiving surface and the light emitting surface. The side surface and the light receiving surface form an included angle within the optical component. The included angle ranges from 100 to 130 degrees.

Through the aforementioned ways, the amount of the emitted light of the light-emitting unit in the display device can be effectively enhanced, so that the whole luminance efficiency can be enhanced.

### BRIEF DESCRIPTION OF THE DRAWINGS

FIG. 1A is a three-dimensional schematic diagram of a display device of an embodiment of the present invention;

FIG. 1B is a cross-sectional diagram of the embodiment illustrated in FIG. 1A;

FIG. 2 is a cross-sectional diagram of another embodiment of the present invention.

FIG. 3A is a three-dimensional schematic diagram of the display device of another embodiment of the present invention;

FIG. 3B is a cross-sectional diagram of the embodiment illustrated in FIG. 3A;

FIG. 4 is a diagram of a variation of the embodiment illustrated in FIG. 3B;

FIG. 5 is a three-dimensional schematic diagram of the display device of another embodiment of the present invention;

FIG. 6 is a cross-sectional diagram of the embodiment illustrated in FIG. 5;

FIG. 7 is a diagram of the display device of another embodiment of the present invention;

FIG. 8A is a three-dimensional schematic diagram of the display device of an embodiment of the present invention;

FIG. 8B is a cross-sectional diagram of the embodiment illustrated in FIG. 8A;

FIG. 9 is a diagram of the variation of the embodiment illustrated in FIG. 8B;

FIG. 10 is a diagram of the variation of the embodiment illustrated in FIG. 8B.

### DETAILED DESCRIPTION OF THE PREFERRED EMBODIMENT

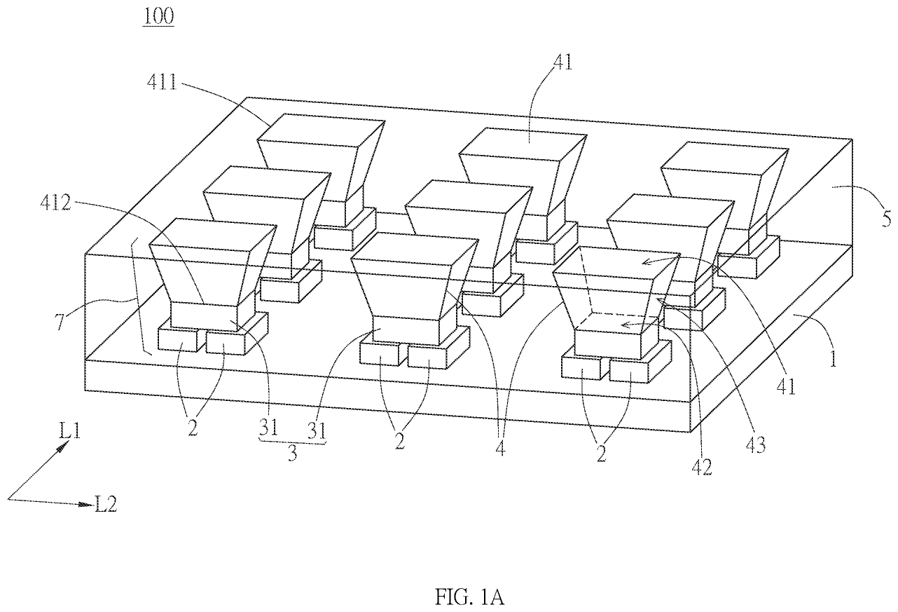

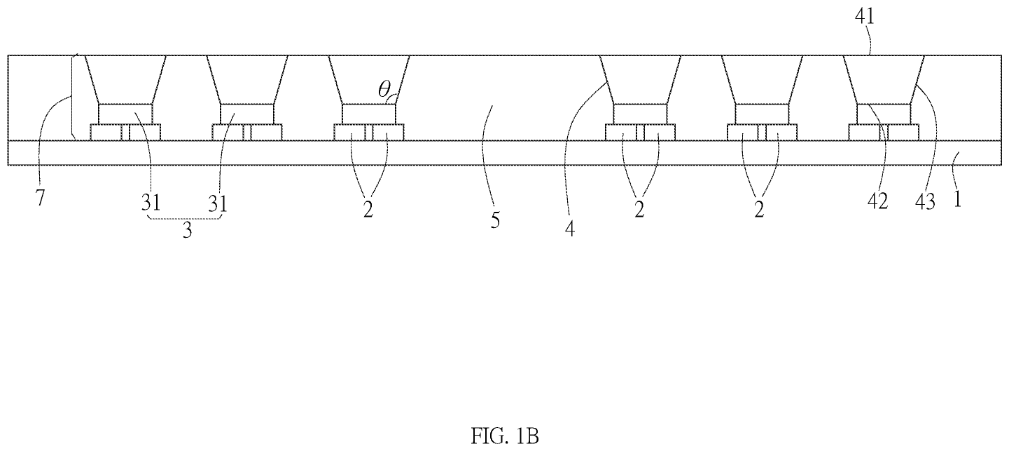

The LED display device disclosed by the present invention will be described in detail below through embodiments and with reference to the accompanying FIG. 1A to FIG. 10. People skilled in the art may understand the advantages and effects of the present disclosure through the contents disclosed in the present specification. However, the contents shown in the following sentences never limit the scope of the present disclosure. Without departing from the conception principles of the present invention, a person having ordinary skill in the present art may realize the present disclosure through other embodiments based on different views and applications.

In the attached drawings, for the purpose of clarification, the diagrams are simplified to illustrate the basic structure of the present invention. Therefore, the structure illustrated in drawings are not based on actual shapes and size ratio. For example, for the purpose of clarification, the sizes of specific elements are amplified. In addition, it should be understood that, when an element such as a layer, a film, a panel, a region or a substrate are described as “being on” or “being connected to” another element, they may be directly on or connected to another element, or there may be other elements therebetween. On the other hand, when an element is described as “directly existing on another element” or “being directly connected to” another element, there is no element therebetween. As used in the present specification, a “connection” may be a physical and/or electrical connection.

A display device 100 according to first embodiment of the present invention will be described below with reference to FIG. 1A to FIG. 1B. The display device 100 includes substrate 1, a plurality of base frames 2, a light source array 3, and a plurality of optical components 4.

First, please refer to FIG. 1A and FIG. 1B. The substrate 1 has a first direction L1 and a second direction L2. The first direction L1 and the second direction L2 are not parallel to each other, and are preferably perpendicular to each other. However, they may also intersect each other at a non-right angle. A plurality of base frames 2 are arranged along the first direction L1 and the second direction L2 of the substrate 1 respectively, so that the plurality of base frames 2 are provided on the substrate 1. The light source array 3 includes a plurality of light sources 31. The light sources 31 are arranged along the first direction L1 and the second direction L2 of the substrate 1 respectively and each of the light sources 31 is provided on the base frames 2. In the present embodiment, the light sources 31, for example, may be a Mini LED, and a control circuit such as a thin film transistor (TFT) control circuit may be provided on the substrate 1. However, the present invention is not limited thereto. In addition, the number of the light sources 31 included in the light source array 3 illustrated in FIG. 1A is used as example only. The number of the light sources 3 actually used is not limited thereto.

The optical component 4 has a light receiving surface 42 and a light emitting surface 41. The area surrounded by the top perimeter 411 of the optical component 4 is the light emitting surface 41, and the area surrounded by the bottom perimeter 412 is the light receiving surface 42. In the present embodiment, each of the optical components 4 is respectively disposed on a light source 31, so that the light receiving surface 42 of the optical component 4 is attached to a light emitting surface on the top portion of a light source 3 as illustrated in FIGS. 1A-1B. The light emitting surface on the top portion of a light source 31 (that is, the side opposite to the substrate 1) is a surface that emits light beam. The emitted light beam enters the optical component 4 via the light receiving surface 42. In the present embodiment, the shape of the optical component 4 is an inverted hexahedron cylinder (wider on the upper side and narrower on the lower side) and has a trapezoid-shaped cross-section. The area of the light receiving surface of the optical component 4 is similar or equal to the area of the top portion of the light source 31, so that the bottom perimeter 412 of the optical component and the top perimeter of the light source 31 can match.

The optical component 4 has a certain transmittance. Therefore, when the light beam of the light source 31 enters the optical component 4 via the light receiving surface 42, the light beam can reach the light emitting surface 41 via the transmittance of the optical component 4 and be emitted, or it can be emitted through the four inclined surfaces adjacent to the light emitting surface 41. In the present embodiment, the optical component 4 is manufactured by cutting or by other means the substrate formed by epitaxy when manufacturing the light sources 31. After that, the manufactured light source 31 and the optical component 4 are transferred to be on top of the substrate 1. However, in another embodiment, the optical component 4 is not limited thereto. The optical component 4 is preferably formed by a transparent material such as Al₂O₃, SiC, or GaN and the like. However, in another embodiment, the optical component 4 may contain inclusions such as different particles in accordance with different design demands. For example, the optical component 4 may be materials with a high refractive index and high light transmittance such as poly (methyl methacrylate) (PMMA), polycarbonate (PC) and the like, so that the light output rate of the light refracted or reflected from the light source 31 can be enhanced by the optical components 4.

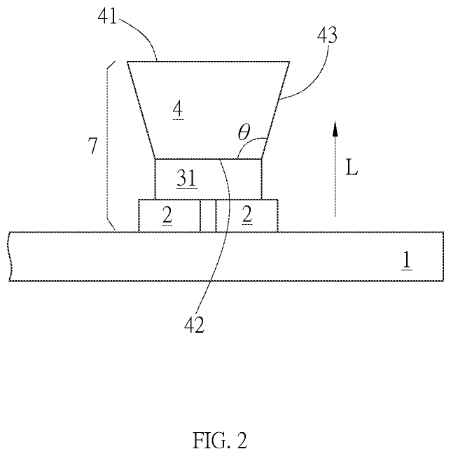

Then, please refer to FIG. 2. FIG. 2 is a side view of the first embodiment of the light emitting diode (LED) display device 100. Wherein, the optical component 4 has a side surface 43. The side surface 43 is connected between the light receiving surface 42 of the optical component 4 and the light emitting surface 41 of the optical component 4. In other words, in the present embodiment, each of the optical components 4 may have four side surfaces 43. An included angle θ is included between the side surface 43 and the light receiving surface 42 of the optical component 4 within the optical component 4. The included angle θ ranges from 100 to 130 degrees. By limiting the included angle θ within the aforementioned range, in the simple case of only having the optical component 4 and the light source 31, when compared to the control group in which the included angle θ is 90 degrees, the amount of light output can be effectively increased by about 37% to 70%. In another embodiment, when the included angle θ further ranges from 105 degrees to 125 degrees, when compared to the control group in which the included angle θ is 90 degrees, the amount of light output can be effectively increased by about 51% to 70%. In another embodiment, when the included angle θ further ranges from 115 degrees to 120 degrees, when compared to the control group in which the included angle θ is 90 degrees, the amount of light output can be effectively increased by about 60% to 70%.

In the embodiment illustrated in FIG. 1A and FIG. 1B, the display device 100 further includes an optical adhesive layer 5, the optical adhesive layer 5 covers the side surface 43 of the optical component 4. In the present embodiment, the optical adhesive layer 5 is a material with high reflectivity, for example, a reflectivity higher than 50%. The higher the reflectivity, the better the light output. In addition, if the optical adhesive layer 5 has the function of partial diffuse reflection, such as a diffuse reflection of 60% of total reflectivity, the light output will be further enhanced. However, the present invention is not limited thereto. In addition, in another embodiment, the optical adhesive layer 5 has an optical adhesive layer refractive index nₑ, and the optical component 4 has an optical refractive index nₒ, wherein the optical adhesive layer refractive index nₑ is smaller than the optical refractive index nₒ. In a preferred embodiment of the present invention, the optical adhesive layer refractive index nₑ preferably ranges from about 1.5 to 1.6, and the optical refractive index nₒ of the optical component 4 may range from about 1.78 to 1.8. Through the aforementioned optical setting for the optical adhesive layer 5, the amount of light output of the light beam of the optical component 4 emitted by the light emitting surface 41 may be enhanced.

The effects of the aforementioned light emitting diode (LED) display device 100 can be varied depending on the properties of the optical adhesive layer 5, such as structures and materials. Therefore, they are not limited to specific values thereto.

In the case of further using the optical adhesive layer 5, when the included angle θ ranges from 100 to 130, compared to the control group in which the included angle θ is 90 degrees, the amount of light output can be still effectively increased by about 8% to 16%. In another embodiment, when the included angle θ further ranges from 105 degree to 125 degree, compared to the control group in which the included angle θ is 90 degrees, the amount of light output can be effectively increased by about 11% to 16%. In another embodiment, when the included angle θ of the optical component 4 with an inclined angle further ranges from 115 degree to 120 degree, compared to the control group in which the included angle θ is 90 degrees, the amount of light output can be effectively increased by about 15% to 16%.

Viewing this from another perspective, the combination of the light source 31 and the optical component 4 in the present embodiment may be viewed as a light-emitting unit 7. The light-emitting units 7 are arranged in the first direction L1 and the second direction L2 of the substrate to form an array and are disposed on the substrate 1, and each of the light-emitting units 7 is disposed in the optical adhesive layer 5. In the present embodiment, the optical adhesive layer 5 is distributed between each of the light-emitting units 7. That is, the optical adhesive layer 5 is filled in the spaces between each of the light-emitting unit 7, so that the optical adhesive layer 5 completely covers the side surfaces 43 of each of the light-emitting units 7. In addition, in the embodiment illustrated in FIG. 1A and FIG. 1B, the top surface of the optical adhesive layer 5 is aligned with the light emitting surface 41 of the optical components 4; therefore, the light beam leaving from the light emitting surface 41 of the optical components 4 will be outwardly emitted. However, in another embodiment, the optical adhesive layer 5 may also extend to cover the light emitting surface 41 of the optical components 4, so that the light leaving from the light emitting surface 41 of the optical components 4 will be outwardly emitted after passing through the optical adhesive layer 5.

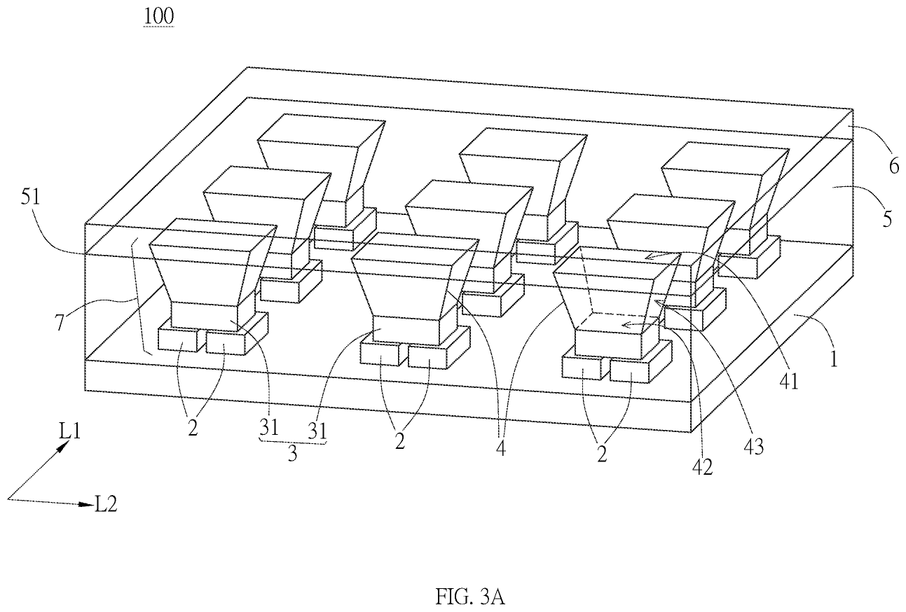

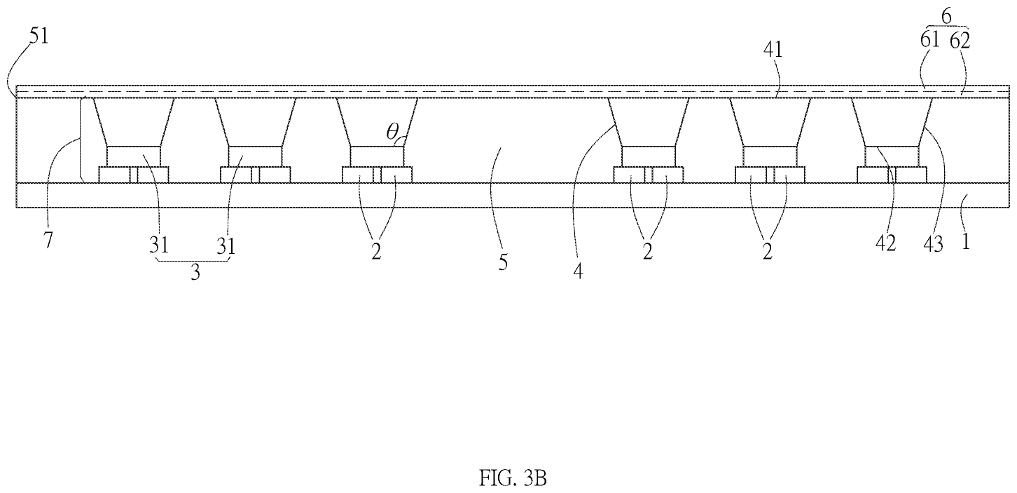

FIG. 3A and FIG. 3B illustrate another embodiment of the display device. In the present embodiment, compared to the embodiment illustrated in FIG. 1A and FIG. 1B, the display device further includes a gradual refractive layer 6 disposed on the light emitting surface 41 of the optical components 4. As illustrated in FIG. 3B, the gradual refractive layer 6 is disposed on the side of the optical adhesive layer 5 opposite to the substrate 1. The optical adhesive layer 5 is aligned with the light emitting surface 41, and the gradual refractive layer 6 extends to be disposed on the light emitting surface 41 and the optical adhesive layer 5. However, in another embodiment, the optical adhesive layer 5 may also extend to be distributed between the light emitting surface 41 and the gradual refractive layer 6. A portion of the gradual refractive layer 6 close to the light emitting surface 41 of the optical components 4 has a first refractive index N1. A portion of the gradual refractive layer 6 away from the light emitting surface 41 has a second refractive index N2. The first refractive index N1 ranges between the second refractive index N2 and the refractive index nₒ of the optical components 4. Specifically, in the present embodiment, the first refractive index N1 ranges between the second refractive index N2 and the refractive index nₑ of the optical adhesive layer 5. For example, when the refractive index nₑ of the optical adhesive layer 5 is 1.58, the refractive index of the gradual refractive layer 6 gradually varies between the refractive index nₑ of the optical adhesive layer 5 (that is, 1.58) and the refractive index (e.g., 1) of the outside medium (such as air). That is, the first refractive index N1 will range between the refractive index nₑ of the optical adhesive layer 5 (that is, 1.58) and the second refractive index N2. In addition, the second refractive index N2 will range between the refractive index of the first refractive index N1 and the refractive index of the outside medium. In the present example, the first refractive index N1 may be 1.45, the second refractive index N2 may be 1.3. Therefore, the spaces between the optical adhesive layer 5 and the outside medium are used as a bridging interface to decrease reflection.

Through such a configuration, compared to the case of using a flat adhesive layer and an uninclined side surface 43 of the optical components 4, in the present embodiment, where the included angle between the side surface 43 and the light receiving surface 42 is 115 degrees and the whole gradual refractive layer 6 is used, the light output can be increased by at least about 24%.

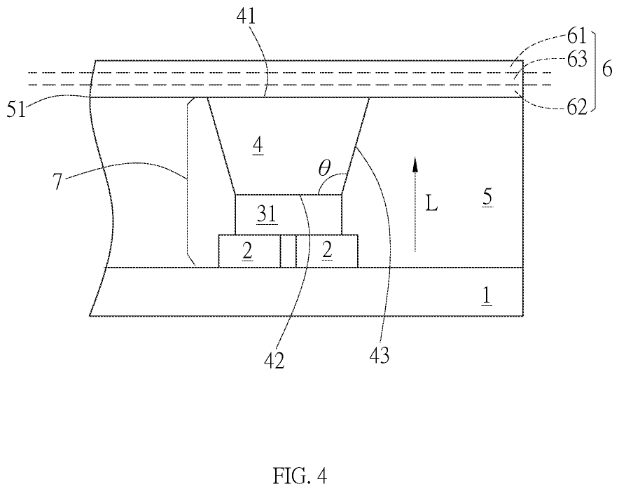

In addition, a first layer 61 can be formed on a surface of the gradual refractive layer 6 close to the optical adhesive layer and away from the substrate 1. The first layer 61 has the first refractive index N1. A second surface 62 can be formed on a surface of the gradual refractive layer 6 away from the optical adhesive layer and close to the substrate 1. The second layer 62 has the second refractive index N2, and the first refractive index N1 is not smaller than the second refractive index N2. In addition, the refractive index between the first layer 61 and the second layer 62 of the gradual refractive layer 6 decreases along the virtual light output direction L of the optical adhesive layer 5, as illustrated in the cross-section view in FIG. 3B. The refractive index of the gradual refractive layer 6 gradually decreases from the second refractive index N2 to the first refractive index N1. In another embodiment, as illustrated in FIG. 4, an intermediate layer 63 is further disposed between the first layer 61 and the second layer 62 of the gradual refractive layer 6. The intermediate layer 63 has a third refractive index N3, the aforementioned concept that the refractive index gradually decreases from the first layer 61 to the second layer 62 is applied to the newly added intermediate layer 63, so that the first refractive index N1 is not smaller than the third refractive index N3, and the third refractive index N3 is not smaller than the second refractive index N2. As mentioned above, through the aforementioned designs, the light beam emitted by the light-emitting unit 7 can directly or indirectly (for example, passing through the optical adhesive layer 5 at midway) enters a subsequent medium after passing through the gradual refractive layer 6, so that the amount of reflected light can be decreased and the light output can be enhanced. In addition, it is specifically noted that number of the intermediate layer 63 is not limited to a single layer and may be multiple layers.

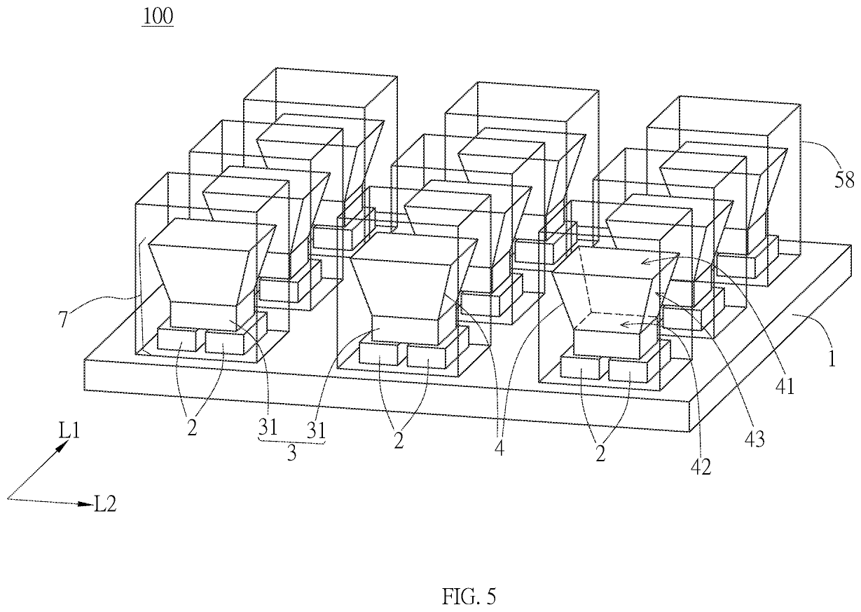

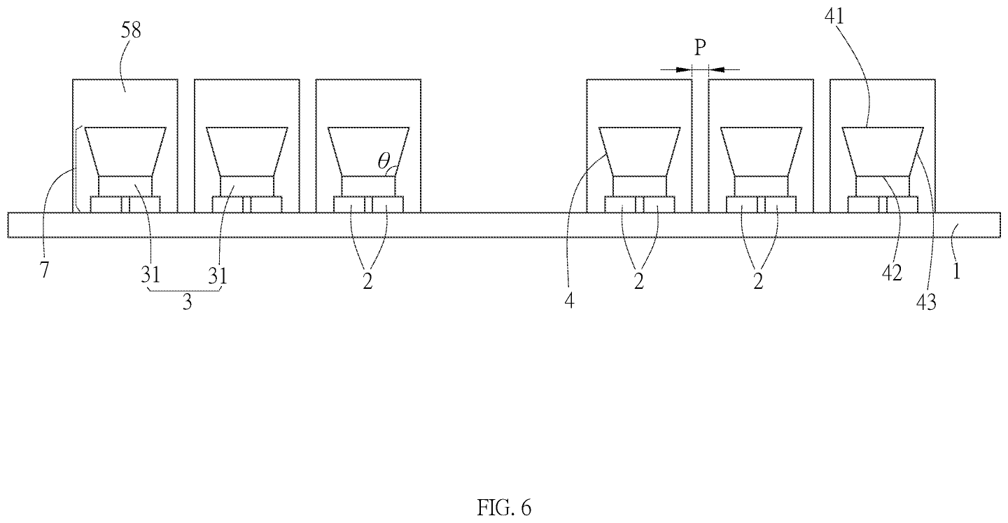

On the other hand, please refer to FIG. 5 and FIG. 6. The optical adhesive layer includes a plurality of plastic blocks 58. The shapes of the plastic blocks 58 are preferably square cylinders and correspondingly cover each of the light-emitting units 7 and the side surface 43 of the optical components 4. As illustrated in FIG. 5 and FIG. 6, gaps P exist between the plastic blocks 58 and they are not connected to each other. However, in another embodiment, when the gaps P exist between each of the plastic blocks 58, portions of the gaps close to the substrate 1 are connected. In other words, the plastic blocks 58 can be formed as the protruding portions in the whole adhesive layer. In addition, the plastic blocks 58 may also be formed in the shape of hexagonal cylinders or other polygonal cylinders. Compared to the case of using a flat adhesive layer and an uninclined side surface 43 of the optical components 4, in the present embodiment, where the included angle between the side surface 43 and the light receiving surface 42 is 115 degrees and the independent square cylinder-shaped plastic blocks 58 are used, the light output can be increased by at least about 50%.

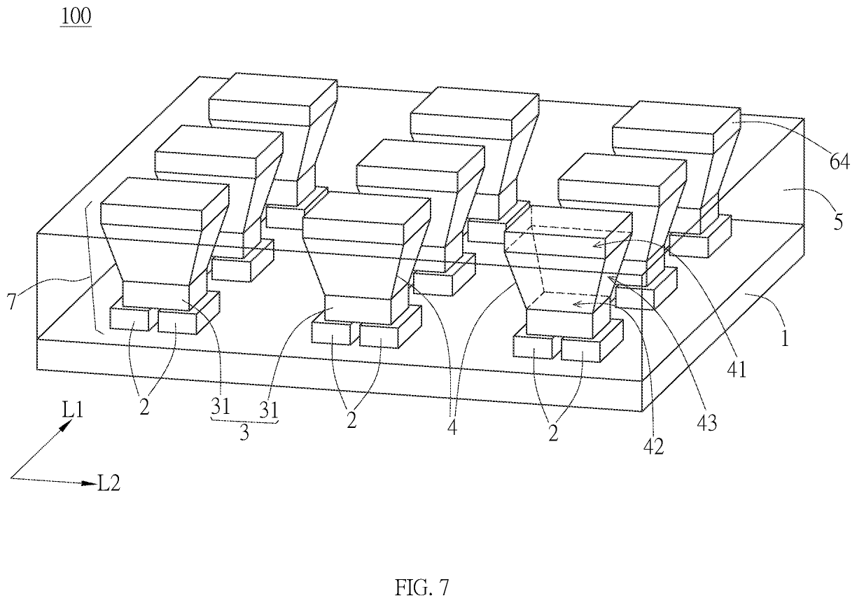

As illustrated by the embodiment in FIG. 7, the gradual refractive layer includes a plurality of gradual refractive units 64 which are independent of each other. Each of the gradual refractive units 64 is respectively disposed on the light emitting surface 41 of each of the optical components 4. And the top surface of the optical adhesive layer 5 is aligned with the light emitting surfaces 41 of the optical components 4, so that the gradual refractive units 64 protrude from the top surface of the optical adhesive layer 5. Through such a configuration, the light beam leaving from the light emitting surfaces 41 of the optical components 4 can directly enter the gradual refractive units 64. However, in another embodiment, the optical adhesive layer 5 may also extend to cover a surface of the gradual refractive units 64 away from the optical components 4. In the present embodiment, the first refractive index N1 ranges between the second refractive index N2 to the refractive index nₒ of the optical components 4. For example, when the refractive index nₒ of the optical components 4 is 1.784, the refractive index of the gradual refractive units 64 gradually varies between the refractive index nₒ of the optical components 4 (that is, 1.784) and the refractive index nₑ of the optical adhesive layer 5 on the other side of the gradual refractive units 64 (for example, 1.58). That is, the first refractive index N1 will range between the refractive index nₒ of the optical components 4 (that is, 1.784) and the second refractive index N2. In addition, the second refractive index N2 will range between the first refractive index N1 and the refractive index nₑ of the optical adhesive layer 5 (for example, 1.58). In the present example, the first refractive index N1 may be 1.7, and the second refractive index N2 may be 1.6. Therefore, a space between the optical components 4 and the optical adhesive layer 5 can be used as a bridging interface to decrease the amount of reflection.

Through such a configuration, compared to the case of using a flat adhesive layer and an uninclined side surface 43 of the optical component 4, in the present embodiment, where the included angle between the side surface 43 and the light receiving surface 42 is 115 degrees and the independent gradual refractive layers 61 is used, the light output can be increased by at least about 43%.

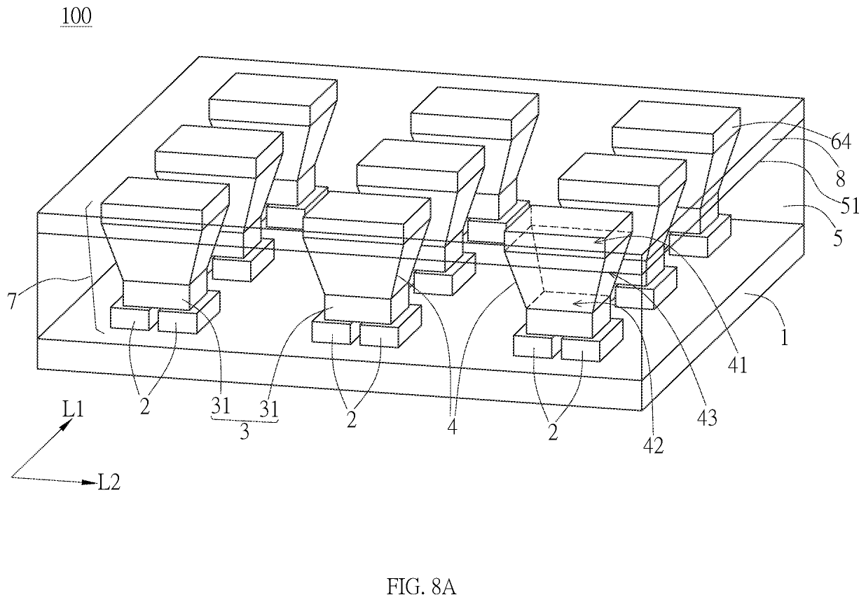

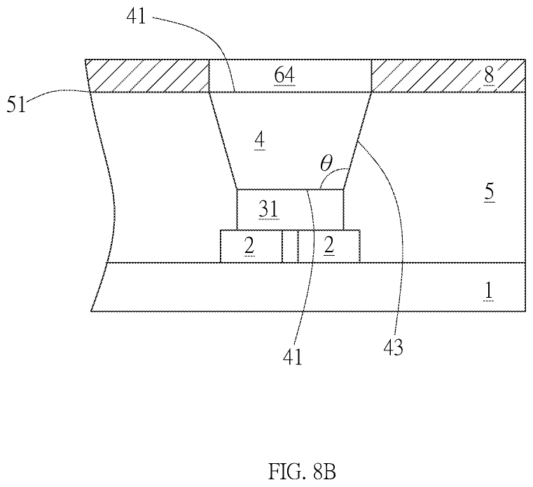

FIG. 8A and FIG. 8B illustrate another embodiment of the present invention. In the present embodiment, an optical absorption material 8 is further included, which is disposed on a surface 51 of the optical adhesive layer 5 away from the substrate 1. In the present embodiment, the light sources 31, the optical components 4 connected to the light sources 31, and the gradual refractive units 64 disposed on the light emitting surfaces 41 of the optical components 4 may be viewed together as the light-emitting unit 7. The light-emitting units 7 are arranged along the first direction L1 and the second direction L2 of the substrate, so that the plurality of light-emitting units 7 are disposed on the substrate 1 to form an array. The optical absorption material 8 is disposed on the surface 51 of the optical adhesive layer 5 between each of the light-emitting units 7 away from the substrate 1, so that the light emitted from the surface 51 is absorbed and the display effect is further enhanced, such as to reduce unnecessary reflection to enhance brightness contrast. In the present embodiment, black ink, toner and vinyl with high optical density can be selected as the optical absorption material 8 to be arranged to form a black matrix. However, the present invention is not limited thereto. The pigment of the optical absorption material 8 can be produced by suitably mixing pigments of various colors.

Specifically, as illustrated in FIG. 8A and FIG. 8B, the optical absorption materials 8 are arranged to form a plurality of openings. In addition, the gradual refractive units 64 respectively protrude beyond the optical adhesive layer 5 and are at least partially accommodated within the openings. In the present embodiment, the gradual refractive units 64 are aligned with the optical absorption material 8, but not limited thereto. For example, the gradual refractive units 64 may protrude beyond the optical absorption material 8 a little. Through such a configuration, when compared to the case of using a flat adhesive layer and an uninclined side surface 43 of the optical components 4, in the present embodiment, where the included angle between the side surface 43 and the light receiving surface 42 is 115 degrees and the gradual refractive units 64 and the optical absorption material 8 are used, the amount of light output can be enhanced by at least about 90% while the reflection level can be decreased by about 60%.

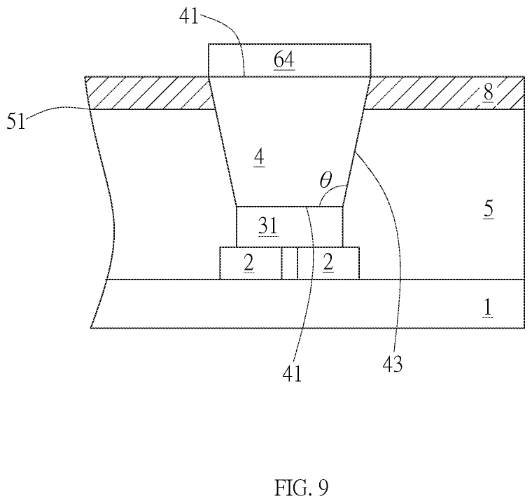

In the embodiment illustrated in FIG. 9, part of the optical components 4 and the gradual refractive units 64 are not covered by the optical adhesive layer 5. Specifically, the optical components 4 has one end of the light emitting surface 41 protruding beyond the optical adhesive layer 5 and at least partially accommodated within the opening formed by the optical absorption material 8. In addition, the gradual refractive units 64 at least partially protrude beyond the optical absorption material 8. Compared to the case of using a flat adhesive and an uninclined side surface 43 of the optical components 4, in the present embodiment, where the included angle between the side surface 43 and the light receiving surface 42 is 115 degrees and the optical adhesive layers 5 of different reflectivities are used, the amount of the light output can be enhanced by about 96% to 143%, while the reflection level can be decreased by about 60%.

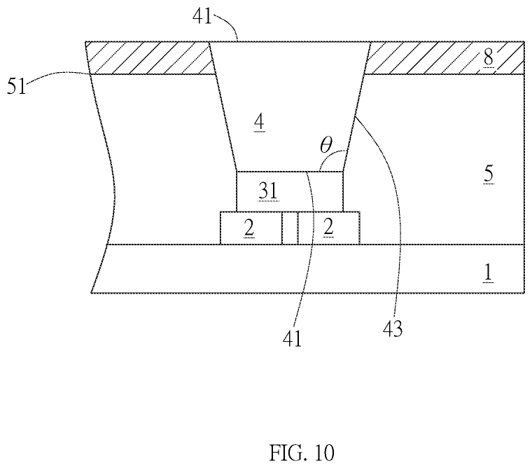

FIG. 10 illustrates a variation of the embodiment illustrated in FIG. 9. When compared to the embodiment illustrated in FIG. 9, the gradual refractive units 64 is not provided in the present embodiment. Specifically, the optical components 4 has one end of the light emitting surface 41 protruding beyond the optical adhesive layer 5 and at least partially accommodated within the opening formed by the optical absorption material 8. In the present embodiment, the light emitting surfaces 41 of the optical components 4 are aligned with the optical absorption material 8 but not limited thereto. For example, it can protrude beyond the optical absorption material 8 a little. Compared to the case of using a flat adhesive layer and an uninclined side surface 43 of the optical components 4, in the present embodiment, where the included angle between the side surface 43 and the light receiving surface 42 is 115 degrees and the optical absorption material 8 surrounding the light emitting surface 41 of the optical components 4 is used, the amount of light output can be enhanced by about 45%, while the reflection level can be decreased by about 60%.

The aforementioned embodiments are some preferred embodiments of the present invention. It should be noted that, without departing from the conception principles of the present invention, the present invention can be varied or modified. People skilled in the art should understand that the scope of the present invention is defined attached claims and variations such as replacement, combination, modification or diversion are included in the scope of the present invention defined by attached claims without departing from the concept of the present invention.

What is claimed is:

1. A display device comprising:
a substrate; and
a light source array having a plurality of light light-emitting units arranged on the substrate, each of the light-emitting units comprises:
a light source provided on the substrate, and a side of light source opposite to the substrate having a light source luminous surface; and
an optical component provided on the light source, each of the optical component having a light receiving surface and a light emitting surface, and the light receiving surface is connected to the light source luminous surface;
wherein the optical component has a side surface connecting the light receiving surface and the light emitting surface, the side surface and the light receiving surface have an included angle therebetween within the optical component, the included angle ranges from 100 degree to 130 degree.

2. The display device according to claim 1, wherein, the included angle further ranges from 105 degree to 125 degree.

3. The display device according to claim 1, wherein, the included angle further ranges from 115 degree to 120 degree.

4. The display device according to claim 1, further comprising an optical adhesive layer arranged to cover the sides of the optical component, wherein the optical adhesive layer has an adhesive layer refractive index, the optical component having an optical component refractive index, and the adhesive layer refractive index is less than the optical component refractive index.

5. The display device according to claim 4, wherein, a top surface of the optical adhesive layer is aligned with the light emitting surface of the optical component, and light leaving from the light emitting surface of the optical component is outwardly emitted after passing through the optical adhesive layer.

6. The display device according to claim 4, the optical adhesive layer having a plurality of plastic blocks, each of the plastic block is configured to correspondingly cover the side of each of the optical component, and gaps exists between each of the plastic blocks.

7. The display device according to claim 6, wherein, the plastic blocks are not connected to each other.

8. The display device according to claim 4, wherein, the reflectivity of the optical adhesive layer is higher than 50%.

9. The display device according to claim 1, further comprising a gradual refractive layer provided opposite to the light emitting surface of the optical component; wherein a portion of the gradual refractive layer relatively closed to the light emitting surface has a first refractive index, and a portion of the gradual refractive layer relatively far from the light emitting surface has a second refractive index, wherein the first refractive index ranges between the second refractive index and an optical component refractive index of the optical component.

10. The display device according to claim 9, wherein, the gradual refractive layer has a first layer and a second layer overlapped with each other, the first layer is closer to the light emitting surface than the second layer, the first layer has the first refractive index; the second layer has the second refractive index.

11. The display device according to claim 10, wherein, the gradual refractive layer has an intermediate layer between the first layer and the second layer, the intermediate layer has a third refractive index, and the third refractive index ranges between the first refractive index and the second refractive index.

12. The display device according to claim 8, wherein, the optical adhesive layer is configured to cover and is aligned with the light emitting surface of the optical component, and the gradual refractive layer is provided extending above the light emitting surface, the first refractive index ranges between the second refractive index and the adhesive layer refractive index.

13. The display device according to claim 8, wherein, the gradual refractive layer having a plurality of gradual refraction units provided independently of each other on the light emitting surfaces of the optical component.

14. The display device according to claim 13, the top surface of the optical adhesive layer is aligned with the light emitting surface of the optical component, so that the gradual refraction unit provides protruding from the top surface of the optical adhesive layer.

15. The display device according to claim 14, wherein, the second refractive index ranges between the first refractive index and the adhesive layer refractive index.

16. The display device according to claim 13, further comprising an optical absorption material, providing on a surface of the optical adhesive layer away from the substrate, wherein the optical absorbing material is arranged to form a plurality of openings, wherein the gradual refractive units each protrude beyond the optical adhesive layer and are at least partially accommodated within the openings.

17. The display device according to claim 13, further comprising an optical absorption material, providing on a surface of the optical adhesive layer away from the substrate, wherein the optical absorbing material is arranged to form a plurality of openings, the optical components having one end of the light emitting surface protruding respectively beyond the optical adhesive layer and at least partially accommodated within the openings, and the gradual refractive units protrude at least partially beyond the light absorbing material.

18. The display device according to claim 4, further comprising an optical absorption material provided on a surface of the optical adhesive layer away from the substrate, wherein the optical absorbing material is arranged to form a plurality of openings, the optical component having one end of the light emitting surface protruding respectively beyond the optical adhesive layer and at least partially accommodated within the openings.

19. The display device according to claim 8, further comprising an optical absorption material provided on a surface of the optical adhesive layer away from the substrate, wherein the optical absorbing material is arranged to form a plurality of openings, the optical component having one end of the light emitting surface protruding respectively beyond the optical adhesive layer and at least partially accommodated within the openings.
